(19) United States
(12) Patent Application Publication
(10) Pub. No.: US 2015/0069338 A1
(43) Pub. Date: Mar. 12, 2015

(54) DISPLAY PANEL AND METHOD OF MANUFACTURING THE SAME

(71) Applicant: Samsung Display Co., Ltd., Yongin-City (KR)

(72) Inventors: Seung-Hwan CHO, Suwon-si (KR); YOONHO KHANG, Yongin-si (KR); DONGJO KIM, Yongin-si (KR); Youngki SHIN, Hwaseong-si (KR); Donghwan SHIM, Yongin-si (KR)

(73) Assignee: Samsung Display Co., Ltd., Yongin-City (KR)

(21) Appl. No.: 14/224,698

(22) Filed: Mar. 25, 2014

(30) Foreign Application Priority Data
Sep. 11, 2013 (KR) 10-2013-0109224

(51) Int. Cl. H01L 27/32; H01L 51/56

(52) U.S. Cl. CPC H01L 27/3276; H01L 27/3262; H01L 51/56; H01L 27/3265; H01L 2227/323
USPC 257/40; 438/23

(57) ABSTRACT

A display panel includes a base substrate, on which a pixel area and a peripheral area are defined, a semiconductor pattern disposed on the base substrate, a display element disposed in the pixel area of the base substrate and a first thin film transistor configured to control the display element, where the first thin film transistor includes an input electrode a first portion of the semiconductor pattern and an output electrode disposed on a second portion of the semiconductor pattern, a third portion of the semiconductor pattern between the first portion and the second portion; and a control electrode disposed on the third portion and insulated from the third portion.

This application claims priority to Korean Patent Application No. 10-2013-0109224, filed on Sep. 11, 2013, and all the benefits accruing therefrom under 35 U.S.C. §119, the content of which in its entirety is herein incorporated by reference.

### BACKGROUND

1. Field

The disclosure relates to a display panel and a method of manufacturing the display panel. More particularly, the disclosure relates to a display panel with improved aperture ratio and a method of manufacturing the display panel.

2. Description of the Related Art

A display panel typically includes a plurality of pixels disposed on a base substrate. The base substrate includes a plurality of pixel areas and a peripheral area disposed adjacent to the pixel areas. In such a display panel, the pixels may be arranged in the pixel areas, respectively.

Each of the pixels includes a display element and a circuit part that controls the display element. The display element and the circuit part included in a pixel are disposed in a corresponding pixel area of the pixel areas. When viewed in a plan view, an aperture ratio of each pixel area is determined by a ratio of an area of the display element to an area of each pixel area. As the circuit part becomes complicated, the aperture ratio is lowered and a manufacturing process of the display panel becomes complicated.

### SUMMARY

The disclosure provides a display panel with improved aperture ratio.

The disclosure provides a method of manufacturing the display panel with a simplified manufacturing process.

Exemplary embodiments of the invention provide a display panel including a base substrate, on which a pixel area and a peripheral area are defined; a semiconductor pattern disposed on the base substrate; a display element disposed in the pixel area of the base substrate; and a first thin film transistor configured to control the display element, where the first thin film transistor includes: an input electrode disposed on a first portion of the semiconductor pattern; an output electrode disposed on a second portion of the semiconductor pattern; a third portion of the semiconductor pattern between the first portion and the second portion; and a control electrode disposed on the third portion and insulated from the third portion.

In an exemplary embodiment, the semiconductor pattern may include a metal oxide semiconductor material.

In an exemplary embodiment, the third portion may include an input area disposed adjacent to the first portion and including a reduced metal from the metal oxide semiconductor material, an output area disposed adjacent to the second portion and including the reduced metal from the metal oxide semiconductor material, and a channel area disposed between the input area and the output area.

In an exemplary embodiment, the input area and the output area may have a predetermined thickness from an upper surface of the third portion, and each of the input area and the output area may include a metal layer including the reduced metal.

In an exemplary embodiment, the display panel may further include: a data line disposed in the peripheral area of the base substrate and connected to the input electrode of the first thin film transistor; and a gate line disposed in the peripheral area of the base substrate and connected to the control electrode of the first thin film transistor, where the data line is disposed on the semiconductor pattern.

In an exemplary embodiment, the display panel may further include: a second thin film transistor configured to control a driving current of the display element; and a capacitor including: a lower electrode connected to the output electrode of the first thin film transistor; and an upper electrode connected to the control electrode of the second thin film transistor, where the display element includes an organic light emitting diode.

In an exemplary embodiment, the output electrode of the first thin film transistor and the lower electrode may include a same material as each other, and the control electrode of the second thin film transistor and the upper electrode may include a same material as each other.

In an exemplary embodiment, the output electrode of the first thin film transistor and the lower electrode may be disposed in a same layer as each other, and the control electrode of the second thin film transistor and the upper electrode may be disposed in a same layer as each other.

In an exemplary embodiment, the organic light emitting diode may include: a first electrode connected to an output electrode of the second thin film transistor; an organic light emitting layer disposed on the first electrode; and a second electrode disposed on the organic light emitting diode.

In an exemplary embodiment, the control electrode of the second thin film transistor and the first electrode of the organic light emitting diode may include a same material as each other.

In an exemplary embodiment, the display panel may further include: an opposite substrate facing the base substrate; and a liquid crystal layer interposed between the base substrate and the opposite substrate, where the display element includes a liquid crystal capacitor

Exemplary embodiments of the invention provide a display panel including a base substrate, a metal oxide semiconductor pattern disposed on the base substrate, a display element disposed on the base substrate, and a thin film transistor configured to control the display element, where the thin film transistor includes: an input electrode disposed on a first portion of the metal oxide semiconductor pattern; a second portion of the metal oxide semiconductor pattern connected to the first portion; an output electrode connected to the second portion of the metal oxide semiconductor pattern and including a reduced metal from the metal oxide semiconductor pattern; and a control electrode disposed on the second portion of the metal oxide semiconductor pattern and insulated from the second portion.

Exemplary embodiments of the invention provide a method of manufacturing the display panel including providing a semiconductor layer and a conductive layer on a base substrate, on which a pixel area and a peripheral area are defined, patterning the semiconductor layer and the conductive layer to form a semiconductor pattern including a first portion, a second portion and a third portion, and to form an input electrode of a thin film transistor disposed on the first portion and an output electrode of the thin film transistor disposed on the second portion, where the third portion of the semiconductor pattern is between the first and second portions, providing a control electrode of the thin film transistor to overlap a first part of the third portion and to be insulated from the semiconductor pattern, where a second part of the third portion is exposed by the control electrode, and providing a display element connected to the output electrode in the pixel area.

In an exemplary embodiment, the method may further include reducing the second part of the third portion exposed by the control electrode to form an input area disposed adjacent to the first portion and including a metal layer, an output area disposed adjacent to the second portion and including a metal layer and a channel area disposed between the input area and the output area, after the providing the control electrode.

In an exemplary embodiment, the patterning the semiconductor layer and the conductive layer may include providing a photoresist layer on the conductive layer, firstly ashing the photoresist layer to remove a portion of the photoresist layer which overlaps the third portion of the semiconductor pattern using a mask, where the mask includes a half-transmissive area which overlaps the third portion of the semiconductor pattern and a non-transmissive area which overlaps the first portion and the second portion of the semiconductor pattern, secondly ashing the photoresist layer to expose a portion of the conductive layer, which is overlaps the third portion of the semiconductor pattern, and etching the conductive layer to expose the third portion of the semiconductor pattern.

In an exemplary embodiment, the patterning the semiconductor layer and the conductive layer may include providing a data line connected to the input electrode of the first thin film transistor and disposed in the peripheral area.

In an exemplary embodiment, the data line may overlap the semiconductor pattern.

According to the exemplary embodiment described herein, the input and output electrodes of the first thin film transistor are directly disposed on the portions of the semiconductor pattern. Therefore, the contact holes for a connection of the input and output electrodes to the portions of the semiconductor pattern are omitted. Thus, the structure of the first thin film transistor used to control the display element becomes simplified, and thus the aperture ratio of the display panel may be increased.

In such embodiments, the components included in the circuit part may be formed through the same process, e.g., the portion of the first thin film transistor and the portion of the capacitor are formed through the same process. Thus, the manufacturing process of the display panel becomes simplified and the manufacturing time of the display panel becomes shortened.

### BRIEF DESCRIPTION OF THE DRAWINGS

The above and other features of exemplary embodiments of the invention will become readily apparent by reference to the following detailed description when considered in conjunction with the accompanying drawings, in which:

FIG. 1 is a plan view showing an exemplary embodiment of a display panel, according to the invention;

FIG. 2 is an equivalent circuit diagram showing an exemplary embodiment of a pixel of a display panel, according to the invention;

FIG. 3 is a plan view showing an exemplary embodiment of a pixel of a display panel, according to an exemplary embodiment of the invention;

FIG. 4 is a cross-sectional view taken along line I-I′ of the display panel in FIG. 3;

FIG. 5 is a second cross-sectional view taken along line II-II′ of the display panel in FIG. 3;

FIGS. 6A and 6B are cross-sectional views showing alternative exemplary embodiments of a display panel, according to the invention;

FIG. 7 is a perspective view showing a portion of an alternative exemplary embodiment of a display panel, according to the invention;

FIG. 8 is an equivalent circuit diagram showing an alternative exemplary embodiment of a pixel of a display panel, according to the invention;

FIG. 9 is a plan view showing an alternative exemplary embodiment of a pixel of a display panel, according to the invention;

FIG. 10 is a cross-sectional view taken along line III-III′ of the display panel in FIG. 9;

FIGS. 11A to 11H are views showing an exemplary embodiment of a manufacturing process of a display panel, according to the invention; and

FIGS. 12A to 12E are cross-sectional views showing an exemplary embodiment of a manufacturing process of the display panel of FIG. 11B.

### DETAILED DESCRIPTION

The invention will be described more fully hereinafter with reference to the accompanying drawings, in which various embodiments are shown. The invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the claims.

Hereinafter, exemplary embodiments of the invention will be described in detail with reference to the accompanying drawings.

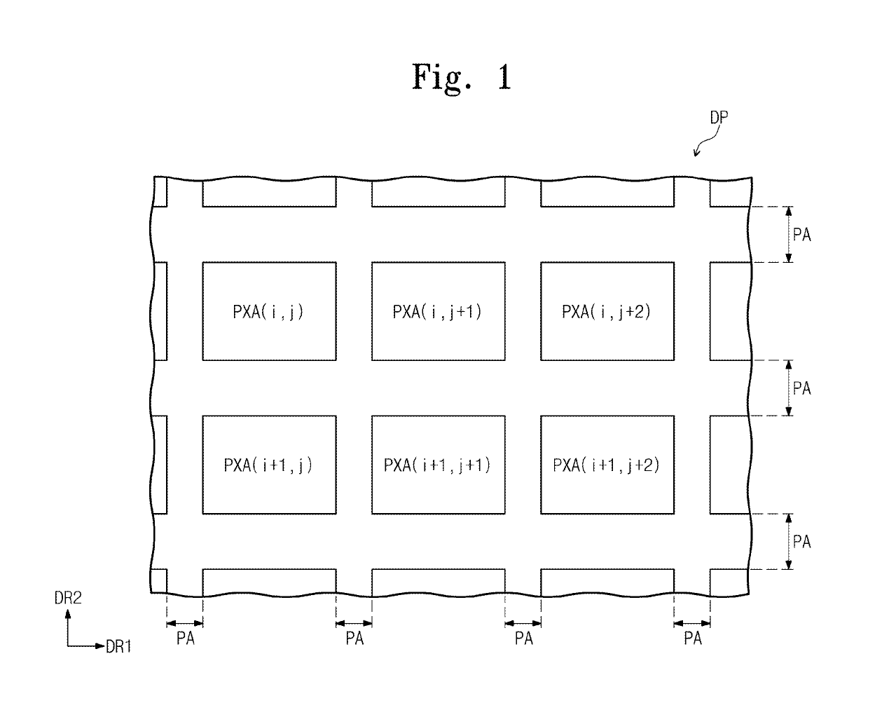

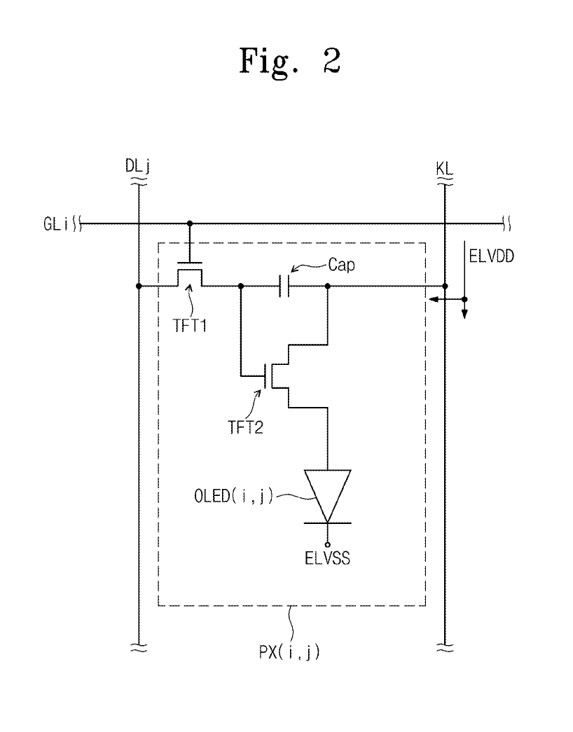

FIG. 1 is a plan view showing an exemplary embodiment of a display panel, according to the invention, and FIG. 2 is an equivalent circuit diagram showing an exemplary embodiment of a pixel, according to the invention.

Referring to FIG. 1, an exemplary embodiment of a display panel DP includes a plurality of pixel areas PXA(i,j) to PXA(i+1,j+2) and a plurality of peripheral areas PA disposed adjacent to the pixel areas PXA(i,j) to PXA(i+1,j+2). The pixel areas PXA(i,j) to PXA(i+1,j+2) are arranged substantially in a matrix form. Here, ‘i’ and ‘j’ are natural numbers. In FIG. 1, only six pixel areas PXA(i,j) to PXA(i+1,j+2) are shown for convenience of illustration, but the invention is not limited thereto.

Among the pixel areas PXA(i,j) to PXA(i+1,j+2), three pixel areas, which are arranged in a same row, display different colors from each other. In one exemplary embodiment, for example, a red color, a green color and a blue color are displayed in the three pixel areas PXA(i,j), PXA(i,j+1) and PXA(i,j+2), respectively.

The display panel DP includes pixels (not shown) disposed in the pixel areas PXA(i,j) to PXA(i+1,j+2) and signal lines (not shown) disposed in the peripheral areas PA. The signal lines are configured to include gate lines that extend substantially in a first direction DR1 and data lines that extend substantially in a second direction DR2. The signal lines may further include a power supply line that extends substantially in the second direction DR2.

In an exemplary embodiment, each pixel may be an organic light emitting pixel. The organic light emitting pixel includes an organic light emitting diode as a display element. In such an embodiment, the organic light emitting pixel includes a thin film transistor to control the organic light emitting diode, but the pixels should not be limited to the organic light emitting pixel.

As shown in FIG. 2, a pixel PX(i,j), e.g., a pixel in an i-th row and j-th column, includes a first thin film transistor TFT1, a capacitor Cap, a second thin film transistor TFT2, and an organic light emitting diode OLED(i,j). The first thin film transistor TFT1, the capacitor Cap and the second thin film transistor TFT2 collectively define a circuit part that controls the organic light emitting diode OLED(i,j).

The pixel PX(i,j) is connected to an i-th gate line GLi and a j-th data line DLj of the signal lines (not shown) disposed in the peripheral areas PA.

The first thin film transistor TFT1 outputs a data signal applied to the j-th data line DLj in response to a gate signal applied to the i-th gate line GLi. The second thin film transistor TFT2 controls a driving current flowing through the organic light emitting diode OLED(i,j) based on an amount of an electric charge charged in the capacitor Cap. The pixel PX(i,j) receives a first voltage ELVDD and a second voltage ELVSS having a different voltage level from the first voltage ELVDD.

A first electrode of the organic light emitting diode OLED(i,j) receives a voltage corresponding to the first voltage ELVDD from the second thin film transistor TFT2, and a second electrode of the organic light emitting diode OLED(i,j) receives the second voltage ELVSS. The organic light emitting diode OLED(i,j) emits light during a turn-on period of the second thin film transistor TFT2, but the invention is not limited thereto. In an alternative exemplary embodiment, the configuration of the pixel PX(i,j) may be variously modified.

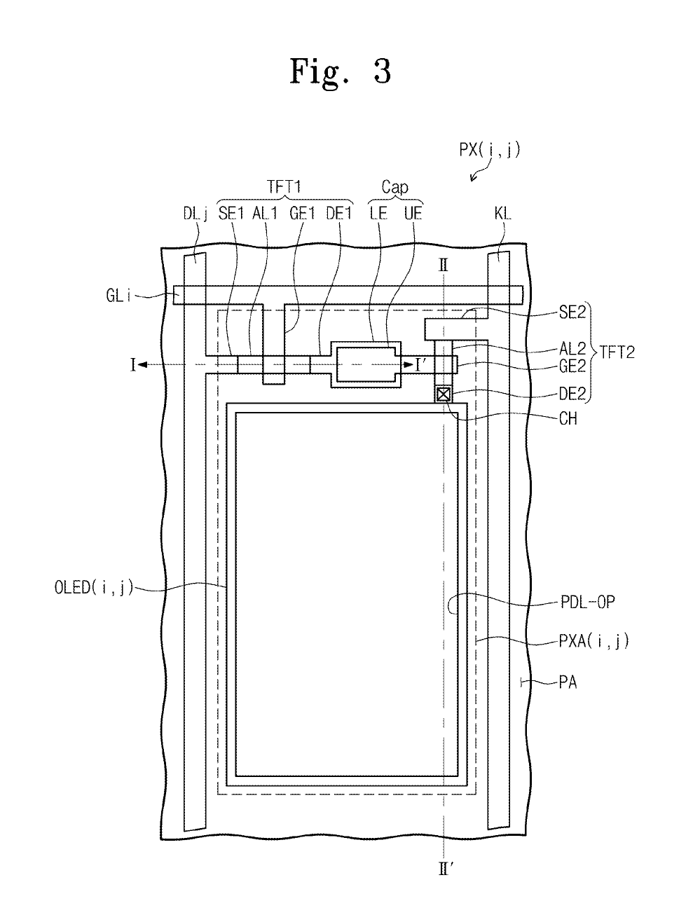

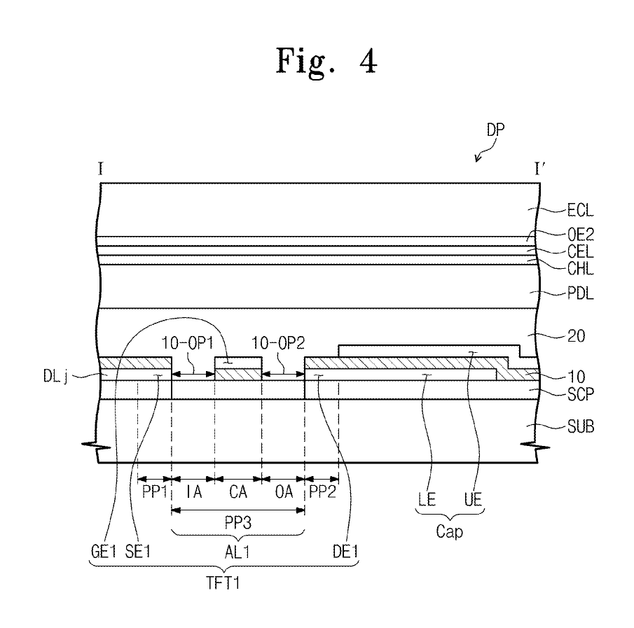

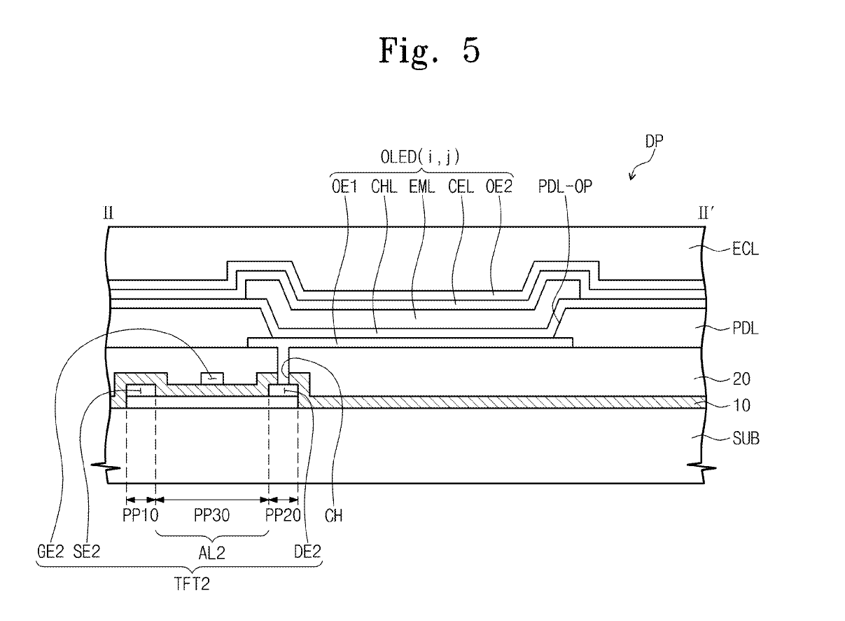

FIG. 3 is a plan view showing an exemplary embodiment of a pixel, according to the invention, FIG. 4 is a cross-sectional view taken along line I-I′ of the display panel in FIG. 3, and FIG. 5 is a cross-sectional view taken along line II-II′ of the display panel in FIG. 3. In FIG. 3, for convenience of illustration, portions of the organic light emitting diode are omitted, and some layers commonly disposed on the display panel are omitted.

In an exemplary embodiment, the display panel DP includes a base substrate SUB. The base substrate SUB may be a glass substrate, a plastic substrate, or a stainless steel substrate, for example.

When viewed in a plan view, the base substrate SUB includes the pixel areas PXA(i,j) to PXA(i+1,j+2) (refer to FIG. 1) and the peripheral areas PA (refer to FIG. 1) disposed adjacent to the pixel areas PXA(i,j) to PXA(i+1,j+2). In FIG. 3, a pixel area PXA(i,j) and the peripheral area PA disposed adjacent to the pixel area PXA(i,j) are illustrated.

In an exemplary embodiment, as shown in FIG. 4, the display panel DP includes a semiconductor pattern SCP disposed on a surface of the base substrate SUB. A portion of the semiconductor pattern SCP defines a portion of the first thin film transistor TFT1 and a portion of the second thin film transistor TFT2. In such an embodiment, the semiconductor pattern SCP is disposed to overlap the j-th data line DLj and the power supply line KL. In an alternative exemplary embodiment, the display panel DP may further include a buffer layer (not shown) arranged on the surface of the base substrate SUB, and the semiconductor pattern SCP may be disposed on the buffer layer.

In an exemplary embodiment, as shown in FIGS. 3 and 4, the first thin film transistor TFT1 includes an input electrode SE1 (hereinafter, referred to as a first input electrode), an output electrode DE1 (hereinafter, referred to as a first output electrode), an active layer AL1 (hereinafter, referred to as a first active layer), and a control electrode GE1 (hereinafter, referred to a first control electrode). The first input electrode SE1 branches from the j-th data line DLj. The first input electrode SE1 and the j-th data line DLj are disposed on the semiconductor pattern SCP. A portion of the semiconductor pattern SCP, which is overlaps the first input electrode SE1, is referred to as a first portion PP1 corresponding to the first thin film transistor TFT1.

The first output electrode DE1 is spaced apart from the first input electrode SE1 when viewed in a plan view. A portion of the semiconductor pattern SCP, which overlap the first output electrode DE1, is referred to as a second portion PP2 corresponding to the first thin film transistor TFT1.

The semiconductor pattern SCP includes a portion (hereinafter, referred to as a third portion PP3 corresponding to the first thin film transistor TFT1) between the first portion PP1 and the second portion PP2 corresponding to the first thin film transistor TFT1. The third portion PP3 of the semiconductor pattern SCP functions as the first active layer AL1 of the first thin film transistor TFT1. The first active layer AL1 corresponds to a channel of the first thin film transistor TFT1.

The first control electrode GE1 is disposed on the third portion PP3 corresponding to the first thin film transistor TFT1 and insulated from the third portion PP3 corresponding to the first thin film transistor TFT1. A first insulating layer 10 is disposed on the base substrate SUB to cover the first input electrode SE1, the first output electrode DE1 and a part of the third portion PP3 corresponding to the first thin film transistor TFT1. The first control electrode GE1 is disposed on the first insulating layer 10 to partially overlap the part of the third portion PP3 corresponding to the first thin film transistor TFT1. In such an embodiment, openings 10-OP1 and 10-OP2 are defined in the first insulating layer 10 to expose the other part of the third portion PP3 corresponding to the first thin film transistor TFT1.

The first insulating layer 10 includes at least one of an inorganic material and an organic material, for example. The first insulating layer 10 may be an organic layer or an inorganic layer. The first insulating layer 10 may have a multi-layer structure. The first insulating layer 10 may have a multi-layer structure of organic layers, a multi-layer structure of inorganic layers, or a multi-layer structure of an organic layer and an inorganic layer.

The semiconductor pattern SCP may include a metal oxide semiconductor material. In one exemplary embodiment, for example, the metal oxide semiconductor material of the semiconductor pattern SCP may include a metal oxide of zinc (Zn), indium (In), gallium (Ga), tin (Sn), titanium (Ti), etc., or a mixture of metal, such as, zinc (Zn), indium (In), gallium (Ga), tin (Sn), titanium (Ti), etc., and an oxides thereof.

The third portion PP3 of the first thin film transistor TFT1 is divided into three areas in accordance with a manufacturing process thereof. The third portion PP3 of the first thin film transistor TFT1 includes an input area IA disposed adjacent to the first portion PP1 corresponding to the first thin film transistor TFT1 and exposed through one opening 10-OP1 (hereinafter, referred to as a first opening), an output area OA disposed adjacent to the second portion PP2 corresponding to the first thin film transistor TFT1 and exposed through the other opening 10-0P2 (hereinafter, referred to as a second opening), and a channel area CA disposed between the input area IA and the output area OA.

During the manufacturing process of the display panel DP, the input area IA and the output area OA may be reduction-treated. Thus, the input area IA and the output area OA include a reduced metal from the metal oxide semiconductor material.

The reduced metal has a predetermined thickness from an upper surface of the third portion PP3 and functions as a metal layer. The metal layer is disposed in each of the input area IA and the output area OA. In such an embodiment, according to the extent of reduction, each of the input area IA and the output area OA may be a metal layer.

The channel area CA corresponds to the channel of the first thin film transistor TFT1. In such an embodiment, the first input electrode SE1 and the first output electrode DE1 of the first thin film transistor TFT1 are directly disposed on the first active layer AL1, such that contact holes for a connection of the first active layer AL1 to the first input electrode SE1 and the first output electrode DE1 may be omitted. Thus, the structure of the first thin film transistor TFT1 becomes simplified, and an aperture ratio of the pixel PX(i,j) is increased.

The capacitor Cap includes a lower electrode LE and an upper electrode UE. The lower electrode LE is connected to the first output electrode DE1 and disposed on the semiconductor pattern SCP. In such an embodiment, the lower electrode LE is disposed in the same layer as the first output electrode DE1. The lower electrode LE and the first output electrode DE1 may be integrally formed as a single unitary and indivisible unit.

The first insulating layer 10 is disposed on the lower electrode LE. The upper electrode UE is disposed on the first insulating layer 10. The upper electrode UE is connected to a control electrode GE2 (hereinafter, referred to as a second control electrode) of the second thin film transistor TFT2. The upper electrode UE and the second control electrode GE2, which are connected to each other, are disposed in the same layer, e.g., on the first insulating layer 10.

The lower electrode LE and the first output electrode DE1 include substantially the same material as each other, and the upper electrode UE and the second control electrode GE2 include substantially the same material as each other. Each of the lower electrode LE and the upper electrode UE may include a metal, such as, aluminum (Al), silver (Ag), copper (Cu), molybdenum (Mo), chromium (Cr), tantalum (Ta), titanium (Ti), etc., or an alloy thereof. In an exemplary embodiment, the lower electrode LE and the upper electrode UE may have a multi-layer structure.

As shown in FIGS. 3 and 5, the second thin film transistor TFT2 includes an input electrode SE2 (hereinafter, referred to as a second input electrode), an output electrode DE2 (hereinafter, referred to as a second output electrode), an active layer AL2 (hereinafter, referred to as a second active layer), and the second control electrode GE2. The second input electrode SE2 branches from the power supply line KL. The second input electrode SE2 is disposed on the semiconductor pattern SCP. A portion of the semiconductor pattern SCP, which overlaps the second input electrode SE2, is referred to as a first portion PP10 corresponding to the second thin film transistor TFT2. Although not shown in figures, the power supply line KL may be disposed on the semiconductor pattern SCP.

When viewed in a plan view, the second output electrode DE2 is disposed to be spaced apart from the second input electrode SE2. The second output electrode DE2 is disposed on the semiconductor pattern SCP. A portion of the semiconductor pattern SCP, which overlaps the second output electrode DE2, is referred to as a second portion PP20 corresponding to the second thin film transistor TFT2.

The semiconductor pattern SCP includes a portion PP30 (hereinafter, referred to as a third portion corresponding to the second thin film transistor TFT2) between the first portion PP10 and the second portion PP20. The third portion PP30 of the semiconductor pattern SCP functions as the second active layer AL2 of the second thin film transistor TFT2. In another exemplary embodiment of the invention, the third portion PP30 corresponding to the second thin film transistor TFT2 may divided into three areas IA, CA and OA as in the third portion PP3 corresponding to the first thin film transistor TFT1 shown in FIG. 4.

The first insulating layer 10 covers the second input electrode SE2, the second output electrode DE2 and the third portion PP30 corresponding to the second thin film transistor TFT2. The second control electrode GE2 is disposed on the third portion PP30 corresponding to the second thin film transistor TFT2 and insulated from the third portion PP30 corresponding to the second thin film transistor TFT2. The second control electrode GE2 overlaps a part of the third portion PP30 corresponding to the second thin film transistor TFT2 and disposed on the first insulating layer 10.

As shown in FIGS. 4 and 5, a second insulating layer 20 is disposed on the first insulating layer 10. The second insulating layer 20 includes at least one of an inorganic material and an organic material. The second insulating layer 20 may be an organic layer. In such an embodiment, where the second insulating layer 20 is the organic layer, the second insulating layer 20 may have a planarized surface, e.g., a substantially flat upper surface.

The second insulating layer 20 may be an inorganic layer. In such an embodiment, where the second insulating layer 20 may be an inorganic layer, the display panel DP further includes an organic layer disposed on the second insulting layer 20 or the inorganic layer to provide a planarized surface. In such an embodiment, the second insulating layer 20 may have a multi-layer structure. The organic layer overlaps a portion of the pixel area PXA(i,j). According to an exemplary embodiment, the second insulating layer 20 may include a multi-layer of organic layers, a multi-layer of inorganic layers, or a multi-layer of an organic layer and an inorganic layer.

The organic light emitting diode OLED(i,j) is disposed on the second insulating layer 20. The organic light emitting diode OLED(i,j) includes a first electrode OE1, a second electrode OE2, and an organic light emitting layer EML disposed between the first electrode OE1 and the second electrode OE2.

The first electrode OE1 is disposed on the second insulating layer 20. The first electrode OE1 is connected to the second output electrode DE2 through a contact hole CH defined through the first and second insulating layers 10 and 20. In an exemplary embodiment, the first electrode OE1 may be an anode and the second electrode OE2 may be a cathode. The first electrode OE1 may include a transparent conductive material or a metal based on a light emitting direction.

A pixel definition layer PDL is disposed on the second insulating layer 20. The pixel definition layer PDL may overlap the pixel area PXA(i,j) and the peripheral area PA. An opening PDL-OP is defined through the pixel definition layer PDL, and the first electrode OE1 is exposed through the opening PDL-OP.

The organic light emitting layer EML is disposed on the first electrode OE1 to overlap the opening PDL-OP. The second electrode OE2 is disposed on the organic light emitting layer EML. A first common layer CHL may be disposed between the first electrode OE1 and the organic light emitting layer EML. A second common layer CEL may be disposed between the organic light emitting layer EML and the second electrode OE2. The first and second common layers CHL and CEL may be commonly disposed not only on the pixel area PXA(i,j) and the peripheral area PA but also on the other pixel areas. The second electrode OE2 may be commonly disposed in substantially the entire pixel areas.

The first common layer CHL include a hole injection layer, and the second common layer CEL includes an electron injection layer. The first common layer CHL may further include a hole transport layer disposed between the hole injection layer and the organic light emitting layer EML, and the second common layer CEL may further include an electron transport layer disposed between the electron injection layer and the organic light emitting layer EML.

A sealing layer ECL is disposed on the second electrode OE2 to cover the organic light emitting diode OLED(i,j). The sealing layer ECL is commonly disposed on the base substrate SUB. In one exemplary embodiment, for example, the sealing layer ECL commonly covers the pixel areas PXA(i,j) to PXA(i+1,j+2) and the peripheral areas PA adjacent to the pixel areas PXA(i,j) to PXA(i+1,j+2). The sealing layer ECL covers substantially the entire pixel areas defined on the base substrate SUB.

In an exemplary embodiment, the display panel DP includes an opposite substrate (not shown) facing the base substrate SUB. The opposite substrate is disposed on the sealing layer ECL. The opposite substrate includes color filters. In an alternative exemplary embodiment according to the invention, the sealing layer may be omitted from the display panel DP. In such an embodiment, where the sealing layer is omitted from the display panel DP, the opposite substrate may function as the sealing layer.

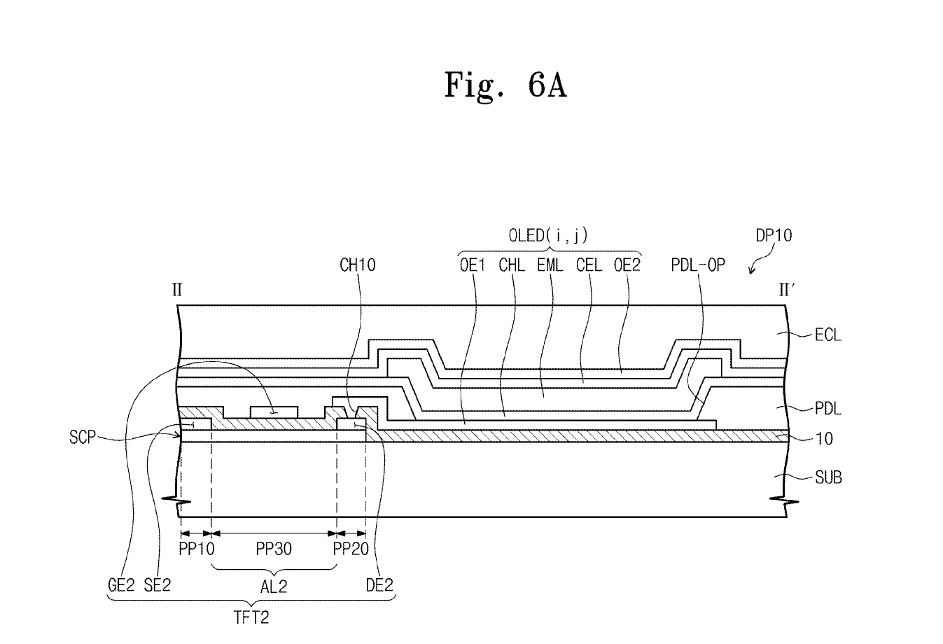

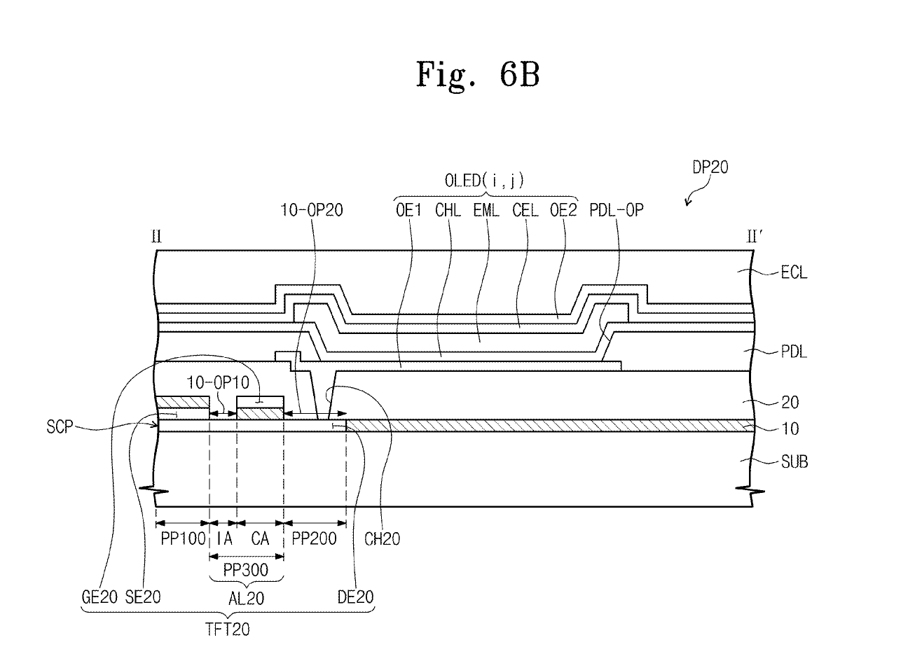

FIGS. 6A and 6B are cross-sectional views showing alternative exemplary embodiments of a display panel, according to the invention. FIGS. 6A and 6B are cross-sections of the display panel corresponding to FIG. 5. Hereinafter, alternative exemplary embodiments of the display panel will be described in detail with reference to FIGS. 6A and 6B. The same or like elements shown in FIGS. 6A and 6B have been labeled with the same reference characters as used above to describe the exemplary embodiments of the display panel shown in FIGS. 1 to 5, and any repetitive detailed descriptions of the same or like elements will be omitted.

Referring to FIG. 6A, in an alternative exemplary embodiment, the first electrode OE1 of the display panel DP10 may be disposed on the first insulating layer 10. The first electrode OE1 is connected to the second output electrode DE2 through a contact hole CH10 defined through the first insulating layer 10. In such an embodiment of the display panel DP10, the second insulating layer 20 shown in FIGS. 3 to 5 is omitted.

In such an embodiment, the first electrode OE1 is disposed in the same layer as the second control electrode GE2, that is, the first electrode OE1 is disposed on the first insulating layer 10. The first electrode OE1 may include the same material as the second control electrode GE2. The first electrode OE1 includes metal, such as, aluminum (Al), silver (Ag), copper (Cu), molybdenum (Mo), chromium (Cr), tantalum (Ta), titanium (Ti), etc., or an alloy thereof. Therefore, the organic light emitting diode OLED(i,j) may emit light to the front direction thereof.

As shown in FIG. 6B, in another alternative exemplary embodiment, the second thin film transistor TFT20 of a display panel includes a second input electrode SE20, a second output electrode DE20, a second active layer AL20 and a second control electrode GE20. The second input electrode SE20 branches from the power supply line KL. The second input electrode SE20 is disposed on the semiconductor pattern SCP. A portion of the semiconductor pattern SCP, which is overlaps the second input electrode SE20, is referred to as a first portion PP100 corresponding to the second thin film transistor TFT2.

The semiconductor pattern SCP further includes a second portion PP200 corresponding to the second thin film transistor TFT2, which is spaced apart from the first portion PP200, and a third portion PP300 corresponding to the second thin film transistor TFT2, which is between the first portion PP100 and the second portion PP200. The third portion PP300 of the semiconductor pattern SCP corresponding to the second thin film transistor TFT2 functions as the second active layer AL20 of the second thin film transistor TFT20.

The third portion PP300 corresponding to the second thin film transistor TFT2 is divided into two areas according to a manufacturing process thereof. The third portion PP300 corresponding to the second thin film transistor TFT2 includes an input area IA disposed adjacent to the first portion PP100 corresponding to the second thin film transistor TFT2 and a channel area CA that overlaps the second control electrode GE20.

The input area IA and the second portion PP200 corresponding to the second thin film transistor TFT2 are exposed through the first insulating layer 10. In such an embodiment, a first opening 10-OP10 is defined in the first insulating layer 10 to expose the input area IA and a second opening 10-OP20 is defined in the first insulating layer 10 to expose the second portion PP200 corresponding to the second thin film transistor TFT2. The input area IA and the second portion PP200 corresponding to the second thin film transistor TFT2 are reduction-treated during the manufacturing process of the display panel DP20. Thus, the input area IA and the second portion PP200 corresponding to the second thin film transistor TFT2 include a metal layer reduced from the metal oxide semiconductor material. The second portion PP200 corresponds to the second output electrode DE20 of the second thin film transistor TFT20.

The second insulating layer 20 is disposed on the first insulating layer 10 to cover the second control electrode GE20. The organic light emitting diode OLED(i,j) is disposed on the second insulating layer 20. The first electrode OE1 is connected to the second output electrode DE20 through a contact hole CH20 defined through the second insulating layer 20. According to another alternative exemplary embodiment, the second insulating layer 20 may be omitted.

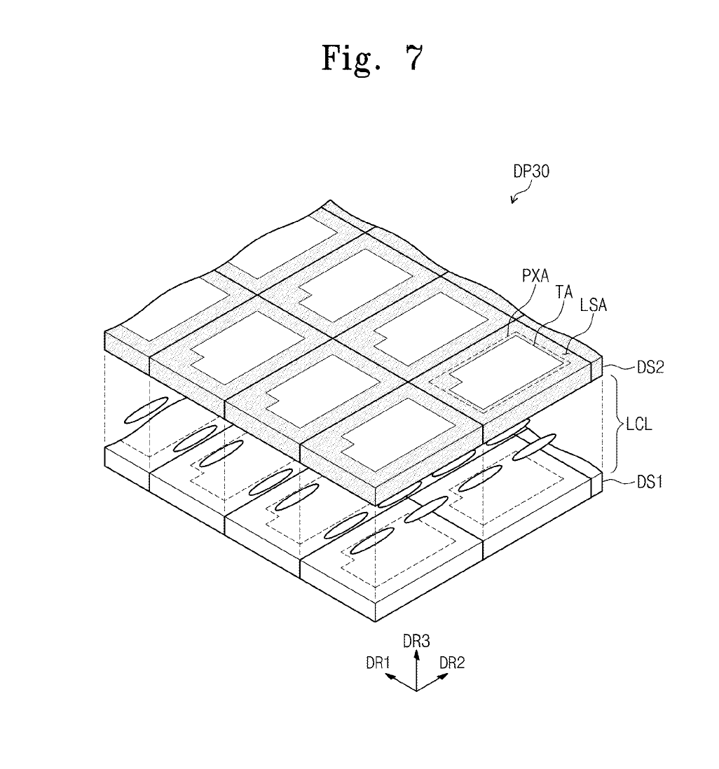

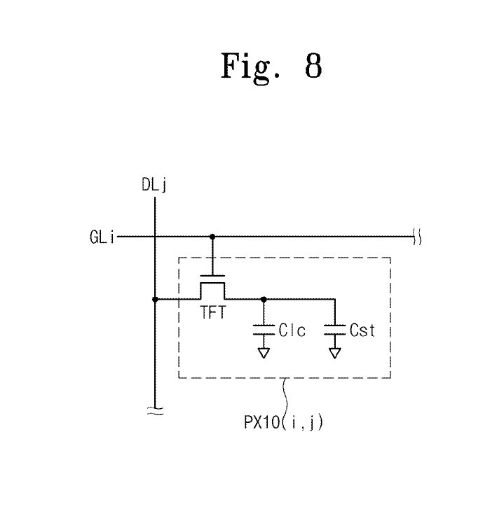

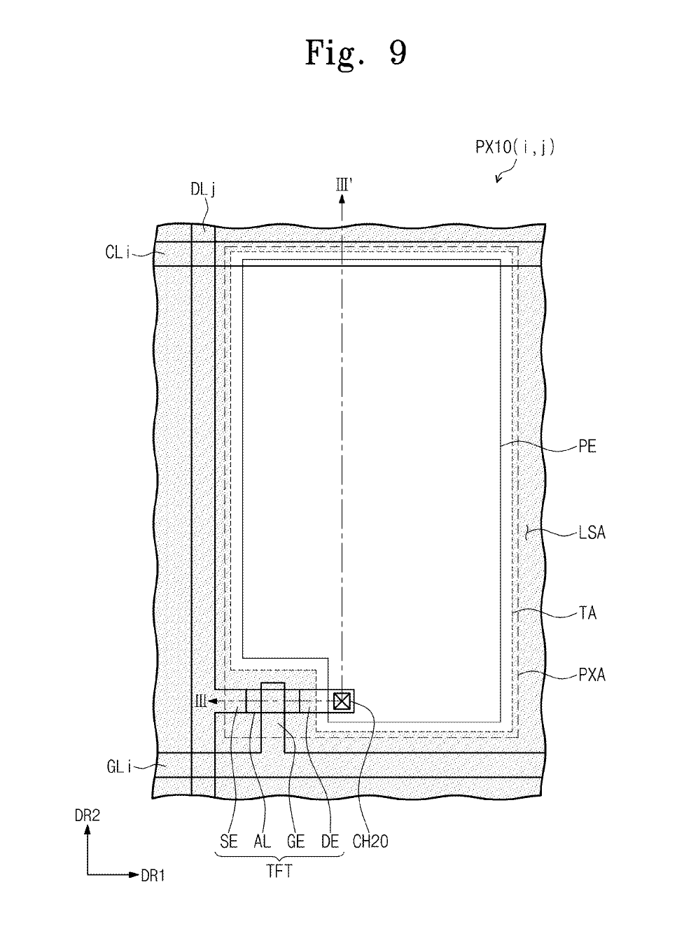

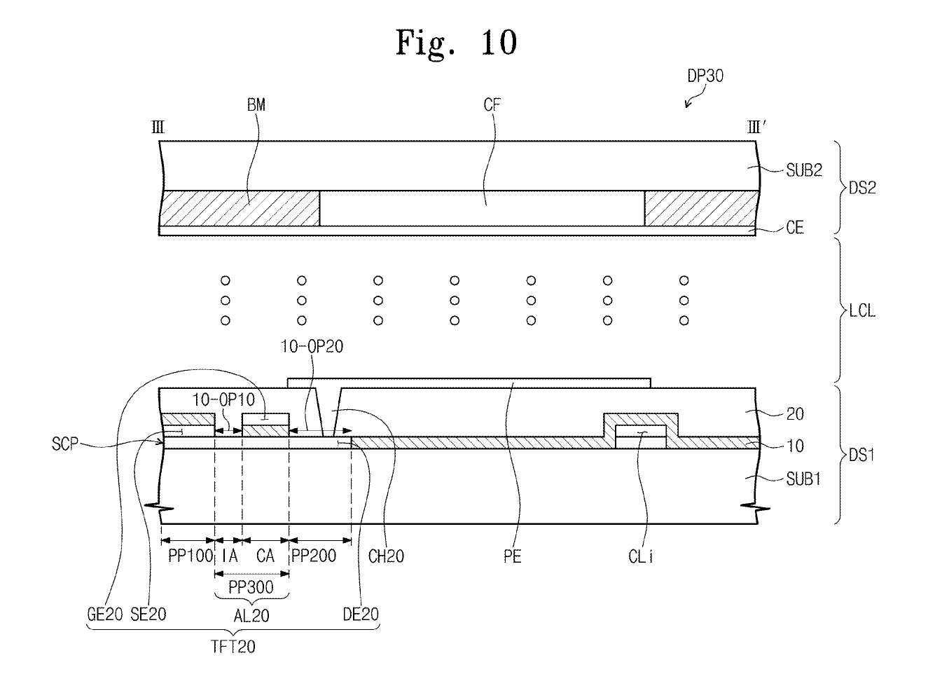

FIG. 7 is a perspective view showing a portion of an alternative exemplary embodiment of a display panel, according to the invention. FIG. 8 is an equivalent circuit diagram showing an alternative exemplary embodiment of a pixel of a display panel, according to the invention. FIG. 9 is a plan view showing an alternative exemplary embodiment of a pixel, according the invention. FIG. 10 is a cross-sectional view taken along line III-III′ of the display panel shown in FIG. 9.

Hereinafter, an alternative exemplary embodiment of a display panel will be described with reference to FIGS. 7 to 10. The same or like elements shown in FIGS. 7 to 10 have been labeled with the same reference characters as used above to describe the exemplary embodiments of the display panel shown in FIGS. 1 to 6, and any repetitive detailed descriptions of the same or like elements will be omitted.

Referring to FIG. 7, in an alternative exemplary embodiment, a display panel DP30 includes a first display substrate DS1 and a second display substrate DS2. The first display substrate DS1 and the second display substrate DS2 are spaced apart from each other in a thickness direction DR3 (hereinafter, referred to as a third direction). In such an embodiment, a liquid crystal layer LCL is interposed between the first display substrate DS1 and the second display substrate DS2.

The display panel DP30 is divided into display areas TA for displaying images and a non-display area LSA disposed adjacent to the display areas TA. The display areas TA transmit light generated from a backlight unit (not shown) and traveling thereto. The non-display area LSA blocks the light generated from the backlight unit and traveling thereto.

The display panel DP30 includes pixels and signal lines for applying signals to the pixels. The pixels are disposed to correspond to the display areas TA, respectively. Each of the pixels includes a display element and a circuit part to control the display element. The display element is disposed in the display area TA. The signal lines are disposed in the non-display area LSA.

As shown in FIG. 7, a pixel area PXA has an area greater than a display area TA corresponding thereto. The pixel area PXA is wider than the display area TA by an area in which the circuit part is accommodated.

Each of the pixels has the same equivalent circuit as a pixel PX10(i,j) shown in FIG. 8. The pixel PX10(i,j) includes a liquid crystal capacitor Clc as the display element and a thin film transistor TFT as the circuit part. In such an embodiment, the pixel PX10(i,j) includes a storage capacitor Cst connected in parallel to the liquid crystal capacitor Clc. In such an embodiment, the storage capacitor Cst may be omitted.

The thin film transistor TFT is connected to a corresponding gate line GLi and a corresponding data line DLj. The thin film transistor TFT outputs a data signal applied to the corresponding data line DLj in response to a gate signal applied to the corresponding gate line GLi.

The liquid crystal capacitor Clc is charged with a voltage corresponding to the data signal. The liquid crystal capacitor Clc includes two electrodes and a liquid crystal layer. The storage capacitor Cst includes one electrode, a portion of a common line as the other electrode thereof, and an insulating layer interposed between the one electrode and the portion of the common line.

The corresponding gate line GLi and the corresponding data line DLj may be disposed on one of the first display substrate DS1 and the second display substrate DS2. The two electrodes of the liquid crystal capacitor Clc may be disposed on one of the first display substrate DS1 and the second display substrate DS2, or disposed on the first and second display substrates DS1 and DS2, respectively, based on the operational mode of the display panel DP30. The liquid crystal capacitor Clc will be described later in greater detail.

FIGS. 9 and 10 show an exemplary embodiment of the pixel PX10(i,j) having the same equivalent circuit as the pixel of FIG. 8. In FIGS. 9 and 10, the pixel PX10(i,j) may be a pixel in an exemplary embodiment of the display panel that operates in a vertical alignment (“VA”) mode is shown.

In such an embodiment, the first display substrate DS1 includes a first base substrate SUB1, an i-th gate line GLi, a j-th data line DLj, a thin film transistor TFT, a plurality of insulating layers 10 and 20, and a pixel electrode PE. The first display substrate DS1 includes a common line CLi that receives a reference voltage. The reference voltage may have substantially the same voltage level as that of a voltage applied to a common electrode CE, which will be described later in detail. In an alternative exemplary embodiment, the common line CLi may be omitted.

The first display substrate DS1 includes a semiconductor pattern SCP disposed on a surface of the first base substrate SUB1. A portion of the semiconductor pattern SCP may define a portion of the thin film transistor TFT. In such an embodiment, the semiconductor pattern SCP may overlap with the j-th data line DLj and the common line CLi.

The thin film transistor TFT includes an input electrode SE, an output electrode DE, an active layer AL, and a control electrode GE. As shown in FIGS. 9 and 10, the thin film transistor TFT has the same structure as that of the second thin film transistor TFT20 shown in FIG. 6B. The input electrode SE, the output electrode DE, the active layer AL and the control electrode GE of the thin film transistor TFT correspond to the second input electrode SE20, the second output electrode DE20, the second active layer AL20 and the second control electrode GE20 of the second thin film transistor TFT20 of FIG. 6B, respectively, and any repetitive detailed description thereof will be omitted.

In an alternative exemplary embodiment, the thin film transistor TFT may have the same structure as one of the thin film transistors TFT1 and TFT2 shown in FIGS. 4 and 5. When the thin film transistor TFT has the structure shown in FIGS. 4 and 5, contact holes for a connection of the portions of the semiconductor pattern SCP to the input electrode SE and the output electrode DE are omitted. Thus, the structure of the thin film transistor TFT becomes simplified, and the aperture ratio of the pixel PX10(i,j) increases.

The first insulating layer 10 covers the common line CLi. The second insulating layer 20 covers the first insulating layer 10 and the thin film transistor TFT. The second insulating layer 20 may provide a planarized surface. The pixel electrode PE is disposed on the planarized surface of the second insulating layer 20. The pixel electrode PE is connected to the output electrode DE through a contact hole CH20 defined through the second insulating layer 20.

The second display substrate DS2 includes a second base substrate SUB2, a black matrix BM, a color filter CF and the common electrode CE. An area where the black matrix BM is disposed corresponds to the non-display area LSA, and an area where the black matrix BM is not disposed corresponds to the display area TA. The color filter CF overlaps the display area TA. The second display substrate DS2 includes color filters having different colors from each other. In one exemplary embodiment, for example, a portion of the color filters has a red color, another portion of the color filters has a green color, and the other portion of the color filters has a blue color.

The common electrode CE is disposed on the black matrix BM and the color filter CF. In an exemplary embodiment, the second display substrate DS2 may further include a planarization layer (not shown) to cover the black matrix BM and the color filter CF. In such an embodiment, the common electrode CE may be disposed on the planarization layer.

The common electrode CE includes a transparent conductive material. The common electrode CE may include a transparent conductive inorganic material, e.g., indium tin oxide (“ITO”) or indium zinc oxide (“IZO”), for example.

The common electrode CE may be disposed on the first base substrate SUB1 according to the operational mode of the display panel DP30, such as, an in-plane switching (“IPS”) mode, a fringe-field switching (“FFS”) mode, and a plane to line switching (“PLS”) mode.

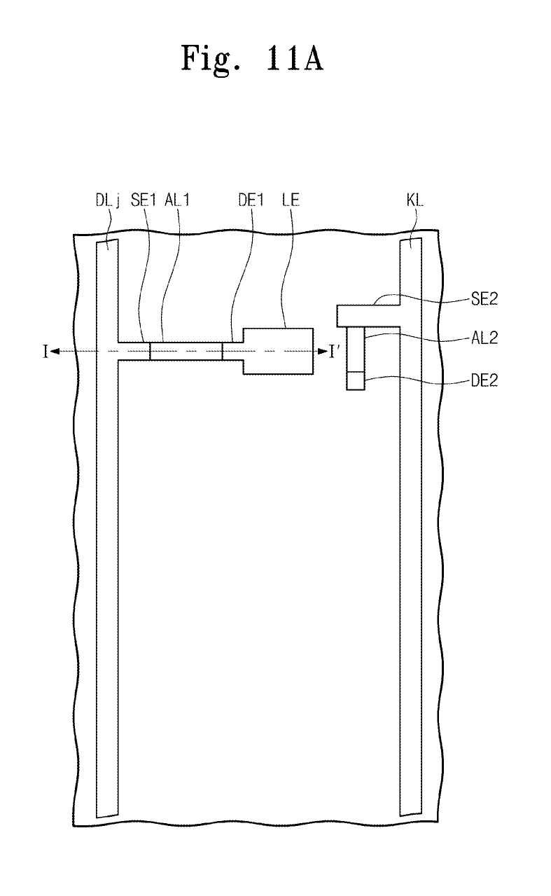

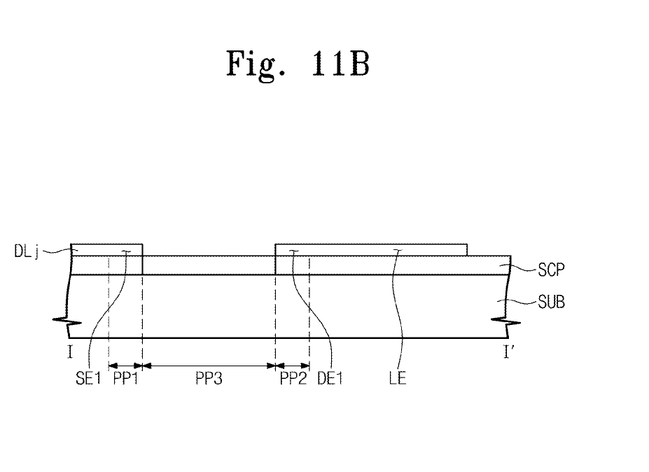

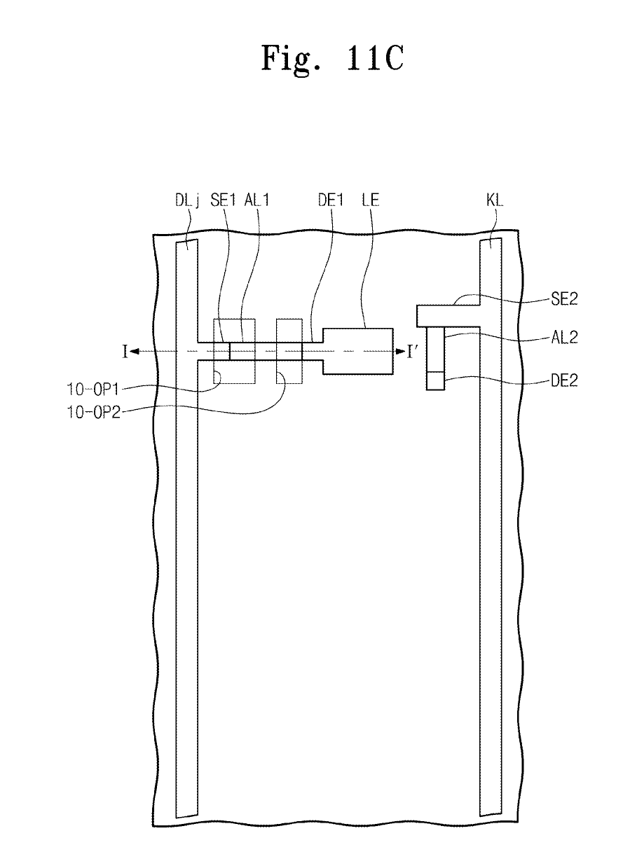

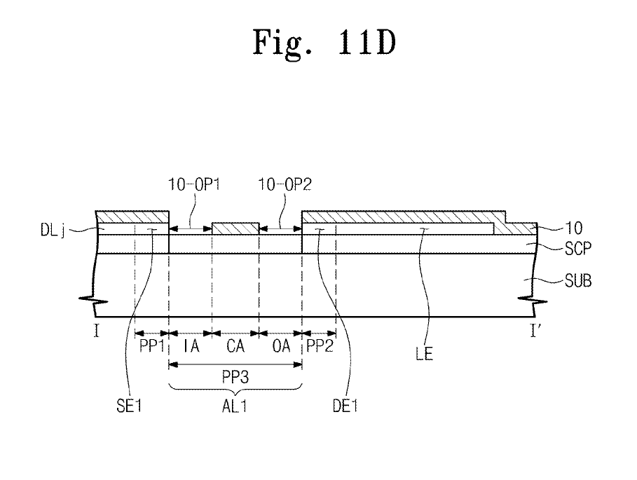

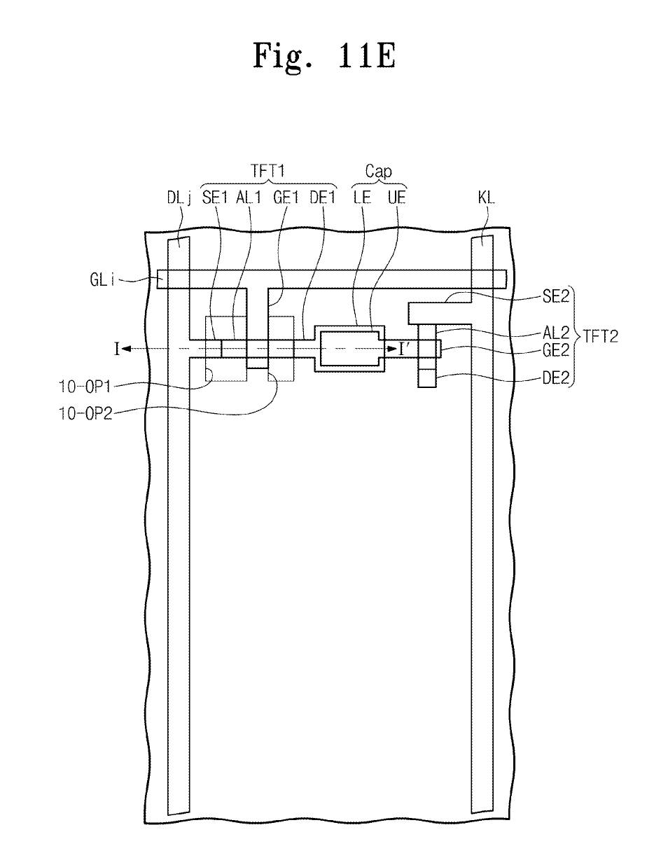

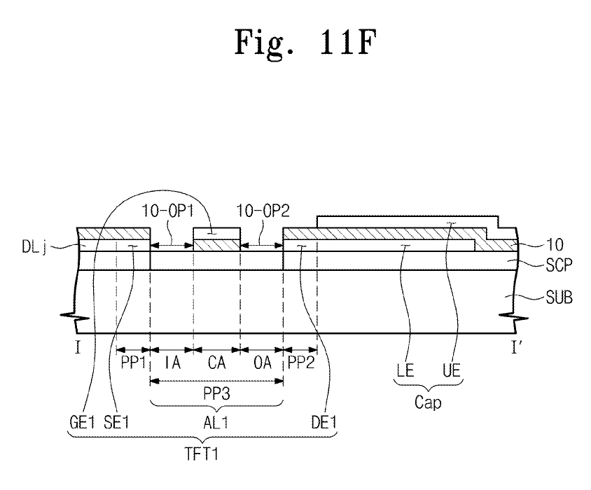

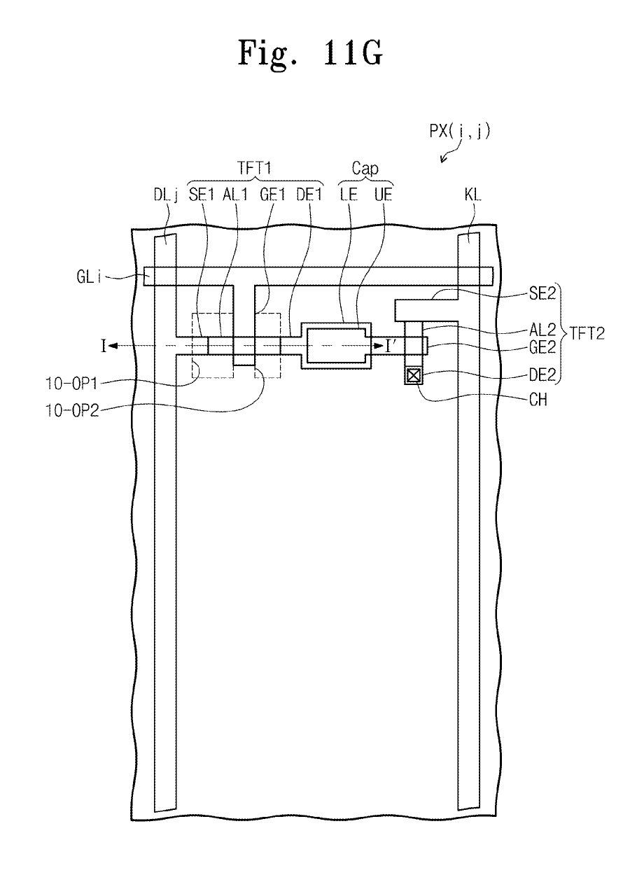

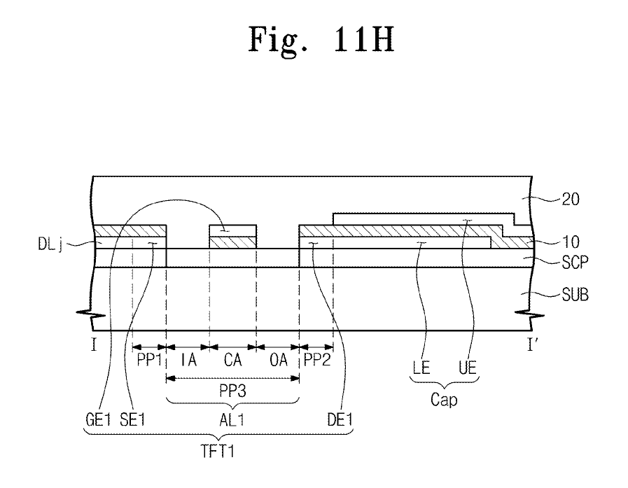

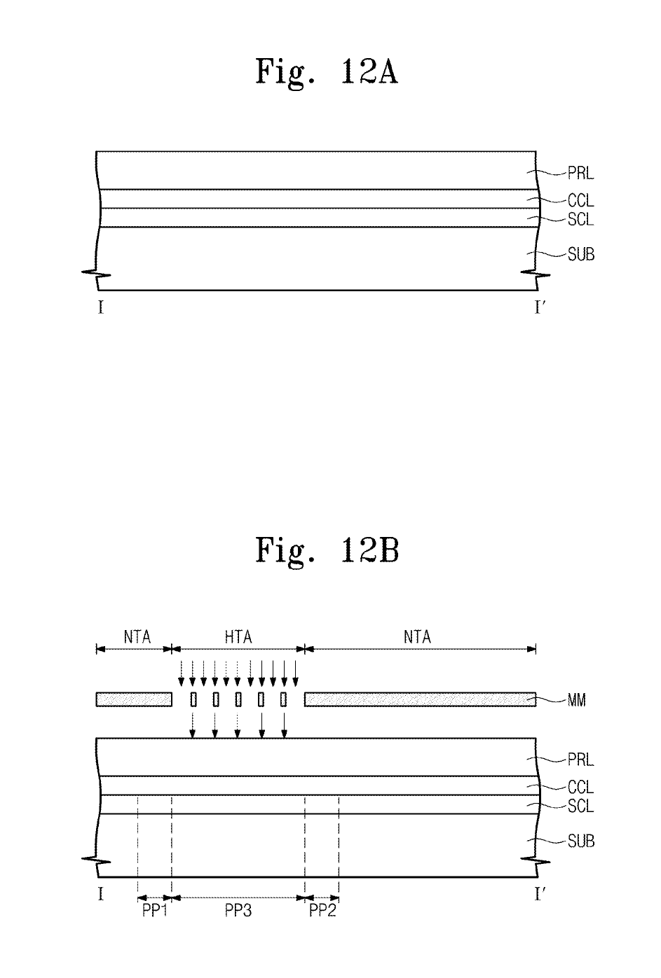

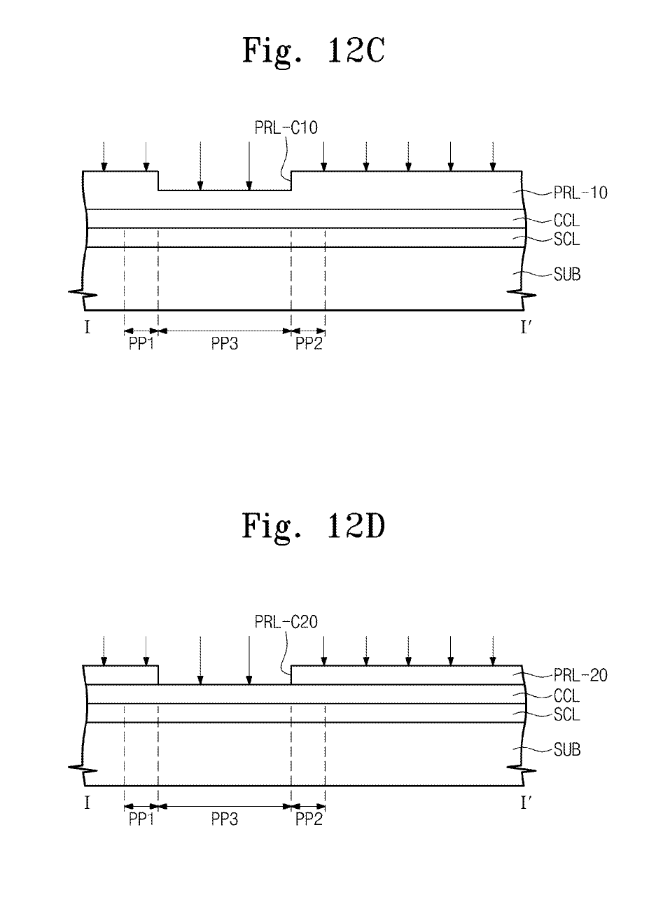

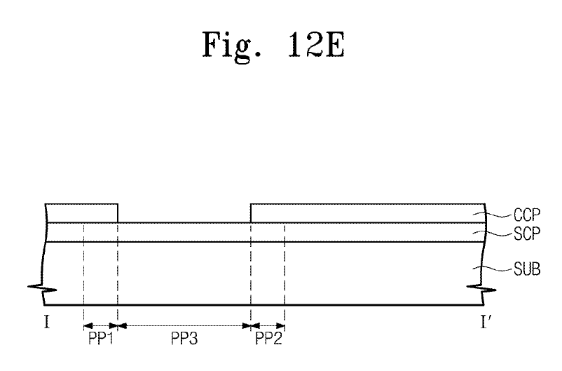

FIGS. 11A to 11H are views showing an exemplary embodiment of a manufacturing process of a display panel, according to the invention. FIGS. 12A to 12E are cross-sectional views showing an exemplary embodiment of a manufacturing process of the display panel shown in FIG. 11B. Hereinafter, an exemplary embodiment of the manufacturing process of the display panel will be described with reference to FIGS. 11A to 12E. FIGS. 11A to FIG. 12E are illustrated with reference to FIGS. 3 and 4. The same or like elements shown in FIGS. 11A to 12E have been labeled with the same reference characters as used above to describe the exemplary embodiments of the display panel shown in FIGS. 3 and 4, and any repetitive detailed description of the same or like elements will be omitted.

As shown in FIGS. 11A to 11B, a semiconductor pattern SCP and a portion of a first thin film transistor TFT1 (refer to FIG. 3) are provided, e.g., formed, on a base substrate SUB.

An input electrode SE1 (hereinafter, referred to as a first input electrode) of the first thin film transistor TFT1 is provided on a first portion PP1 of the semiconductor pattern SCP, and an output electrode DE1 (hereinafter, referred to as a first output electrode) of the first thin film transistor TFT1 is provided on a second portion PP2 of the semiconductor pattern SCP. A third portion PP3, which is disposed between the first portion PP1 and the second portion PP2, is exposed to an exterior.

In an exemplary embodiment, a portion of a capacitor Cap (refer to FIG. 3), a portion of a second thin film transistor TFT2 (refer to FIG. 3) and a power supply line KL may be substantially simultaneously provided using the same process with the portion of the first thin film transistor TFT1.

A lower electrode LE of the capacitor Cap is provided using the same process as the first output electrode DE1. The lower electrode LE of the capacitor Cap connected to the first output electrode DE1 is substantially simultaneously patterned with the first output electrode DE1 using the same etching process. Thus, the lower electrode LE is provided on the semiconductor pattern SCP.

In such an embodiment, an input electrode SE2 (hereinafter, referred to as a second input electrode), an output electrode DE2 (hereinafter, referred to as a second output electrode) of the second thin film transistor TFT2 and the power supply line KL may be substantially simultaneously provided along with the first input electrode SE1 and the first output electrode DE1. The second input electrode SE2, the second output electrode DE2 and the power supply line KL are provided on the semiconductor pattern SCP. A third portion PP30 of the semiconductor pattern SCP, which defines an active layer AL2 (hereinafter, referred to as a second active layer) of the second thin film transistor TFT2, is exposed to an exterior.

A patterning process of a semiconductor layer and a conductive layer will be described in detail with reference to FIGS. 12A to 12E. FIGS. 12A to 12E are illustrated with reference to FIG. 4.

As shown in FIG. 12A, a semiconductor layer SCL and a conductive layer CCL are sequentially provided on the base substrate SUB. In such an embodiment, the semiconductor layer SCL includes a metal oxide semiconductor material. The conductive layer CCL may include a metal, such as, aluminum (Al), silver (Ag), copper (Cu), molybdenum (Mo), chromium (Cr), tantalum (Ta), titanium (Ti), or an alloy thereof. The conductive layer CCL may have a multi-layer structure.

A photoresist layer PRL is provided on the semiconductor layer SCL and the conductive layer CCL. The semiconductor layer SCL and the conductive layer CCL are patterned through a photolithography process and an etching process.

As shown in FIG. 12B, the photoresist layer PRL is exposed to light and developed using a mask MM. The mask MM includes a half-transmissive area HTA disposed to overlap the third portion PP3 and a non-transmissive area NTA disposed to overlap at least the first portion PP1 and the second portion PP2. In one exemplary embodiment, for example, the mask MM may be a half-tone mask.

A portion of the photoresist layer PRL, which overlaps the third portion PP3, is exposed to the light. The photoresist layer PRL is firstly ashed to remove the exposed portion of the photoresist layer PRL, which overlaps the third portion PP3.

As shown in FIG. 12C, due to the first ashing process, a groove PRL-C10 is formed in the photoresist layer PRL. Then, the photoresist layer PRL, in which the groove PRL-C10 is formed, is secondly ashed, and the photoresist layer PRL, in which the groove PRL-C10 is formed, is substantially entirely ashed.

Referring to FIG. 12D, the whole thickness of the photoresist layer PRL is decreased after the second ashing process. The groove PRL-C10 is deformed to become an opening PRL-C20. The opening PRL-C20 exposes a portion of the conductive layer CCL that overlaps the third portion PP3. Then, the exposed portion of the conductive layer CCL is etched.

As shown in FIG. 12E, a portion of the conductive layer CCL, which is not covered or protected by the photoresist layer PRL, is removed. Thus, the third portion PP3 of the semiconductor layer SCL is exposed from the conductive layer CCL. Then, a remaining photoresist layer PRL is removed.

According to the above-described process, the semiconductor pattern SCP including the exposed third portion PP3 is provided.

In an exemplary embodiment, after patterning the semiconductor layer SCL and the conductive layer CCL, a control electrode GE1 (hereinafter, referred to as a first control electrode) of the first thin film transistor TFT1, which overlaps at least a part of the third portion PP3 and is insulated from the third portion PP3, is provided.

As shown in FIGS. 11C and 11D, an insulating layer is provided on the base substrate SUB. In such an embodiment, a first insulating layer 10 is provided to cover at least the first input electrode SE1 and the first output electrode DE1. As shown in FIG. 11C, the first opening 10-OP1 and the second opening 10-OP2, which respectively expose the first portion PP1 and the second portion PP2, are formed in the first insulating layer 10. The first opening 10-OP1 and the second opening 10-OP2 may be formed by an ashing process. In an alternative exemplary embodiment, a plurality of insulating layers may be provided on the base substrate SUB.

Then, as shown in FIGS. 11E and 11F, the first control electrode GE1 is provided on the first insulating layer 10 to overlap at least a part of the third portion PP3. In such an embodiment, the first control electrode GE1 may be formed by a photolithography process and an etching process after a conductive layer is formed on the first insulating layer 10. In such an embodiment, the i-th gate line GLi may be formed together with the first control electrode GE1. In such an embodiment, an upper electrode UE and a control electrode GE2 (hereinafter, referred to as a second control electrode) of the second thin film transistor TFT2 connected to the upper electrode UE may be substantially simultaneously formed with the first control electrode GE1.

Referring to FIGS. 11G and 11H, a second insulating layer 20 is provided on the first insulating layer 10 to cover the first control electrode GE1 and the upper electrode UE. Also, a contact hole CH is formed through the first and second insulating layers 10 and 20. The contact hole CH may be formed using an ashing process or a laser drilling process.

In such an embodiment, a display element (not shown) is provided after the above-described process. The organic light emitting diode OLED(i,j) shown in FIGS. 3 and 5 is formed by performing a conventional deposition process on an organic layer/an inorganic layer and a patterning process on a conductive layer. In such an embodiment, the deposition process on the organic layer/the inorganic layer is repeatedly performed on the organic light emitting diode OLED(i,j) to form a sealing layer ECL, and then, the display panel shown in FIGS. 3 and 5 is formed.

In such an embodiment, the pixel electrode PE shown in FIGS. 9 and 10 is formed by performing a conventional patterning process on a conductive layer. After a second display substrate DS2 is provided, the first display substrate DS1 and the second display substrate DS2 are coupled to each other. In an exemplary embodiment, where the display panel is a liquid crystal display panel, a liquid crystal material is injected between the first and second display substrates DS1 and DS2, such that the liquid crystal layer LCL is formed between the first and second display substrates DS1 and DS2, thereby manufacturing the display apparatus as shown in FIGS. 9 and 10 is performed.

Although some exemplary embodiments of the invention have been described herein, it is understood that the invention should not be limited to these exemplary embodiments but various changes and modifications can be made by one ordinary skilled in the art within the spirit and scope of the invention as hereinafter claimed.

What is claimed is:

1. A display panel comprising:
a base substrate on which a pixel area and a peripheral area are defined;
a semiconductor pattern disposed on the base substrate;
a display element disposed in the pixel area of the base substrate; and
a first thin film transistor configured to control the display element, wherein the first thin film transistor comprises:
an input electrode disposed on a first portion of the semiconductor pattern;
an output electrode disposed on a second portion of the semiconductor pattern;
a third portion of the semiconductor pattern between the first portion and the second portion; and
a control electrode disposed on the third portion and insulated from the third portion.

2. The display panel of claim 1, wherein the semiconductor pattern comprises a metal oxide semiconductor material.

3. The display panel of claim 2, wherein the third portion comprises:
an input area disposed adjacent to the first portion and comprising a reduced metal from the metal oxide semiconductor material;
an output area disposed adjacent to the second portion and comprising the reduced metal from the metal oxide semiconductor material; and
a channel area disposed between the input area and the output area.

4. The display panel of claim 3, wherein
the input area and the output area have a predetermined thickness from an upper surface of the third portion, and
each of the input area and the output area comprises a metal layer comprising the reduced metal.

5. The display panel of claim 2, further comprising:
a data line disposed in the peripheral area of the base substrate and connected to the input electrode of the first thin film transistor; and
a gate line disposed in the peripheral area of the base substrate and connected to the control electrode of the first thin film transistor,
wherein the data line is disposed on the semiconductor pattern.

6. The display panel of claim 2, further comprising:
a second thin film transistor configured to control a driving current of the display element; and
a capacitor comprising:
a lower electrode connected to the output electrode of the first thin film transistor; and
an upper electrode connected to a control electrode of the second thin film transistor,
wherein the display element comprises an organic light emitting diode.

7. The display panel of claim 6, wherein
the output electrode of the first thin film transistor and the lower electrode comprise a same material as each other, and
the control electrode of the second thin film transistor and the upper electrode comprise a same material as each other.

8. The display panel of claim 6, wherein
the output electrode of the first thin film transistor and the lower electrode are disposed in a same layer as each other, and
the control electrode of the second thin film transistor and the upper electrode are disposed in a same layer as each other.

9. The display panel of claim 6, wherein the organic light emitting diode comprises:
a first electrode connected to an output electrode of the second thin film transistor;
an organic light emitting layer disposed on the first electrode; and
a second electrode disposed on the organic light emitting diode.

10. The display panel of claim 9, wherein the control electrode of the second thin film transistor and the first electrode of the organic light emitting diode comprise a same material as each other.

11. The display panel of claim 1, further comprising:
an opposite substrate facing the base substrate; and
a liquid crystal layer interposed between the base substrate and the opposite substrate,
wherein the display element comprises a liquid crystal capacitor.

12. A display panel comprising:
a base substrate:
a metal oxide semiconductor pattern disposed on the base substrate;
a display element disposed on the base substrate; and
a thin film transistor configured to control the display element, wherein the thin film transistor comprises:
an input electrode disposed on a first portion of the metal oxide semiconductor pattern;
a second portion of the metal oxide semiconductor pattern connected to the first portion;
an output electrode connected to the second portion of the metal oxide semiconductor pattern and comprising a reduced metal from the metal oxide semiconductor pattern; and
a control electrode disposed on the second portion of the metal oxide semiconductor pattern and insulated from the second portion.

13. The display panel of claim 12, wherein the second portion comprises:
an input area connected to the first portion and comprising the reduced metal from the metal oxide semiconductor pattern; and
a channel area connected to the input area and which overlaps the control electrode.

14. The display panel of claim 13, further comprising:
an insulating layer which covers the thin film transistor,
wherein the display element comprises an electrode connected to the output electrode through a contact hole defined through the insulating layer.

15. A method of manufacturing a display panel, comprising:
providing a semiconductor layer and a conductive layer on a base substrate, on which a pixel area and a peripheral area are defined;
patterning the semiconductor layer and the conductive layer to form a semiconductor pattern comprising a first portion, a second portion and a third portion, and to form an input electrode of a thin film transistor disposed on the first portion and an output electrode of the thin film transistor disposed on the second portion, wherein the third portion of the semiconductor pattern is between the first and second portions;
providing a control electrode of the thin film transistor to overlap a first part of the third portion and to be insulated from the semiconductor pattern, wherein a second part of the third portion of the semiconductor pattern is exposed by the control electrode; and
providing a display element connected to the output electrode in the pixel area.

16. The method of claim 15, wherein the semiconductor pattern comprises a metal oxide semiconductor material.

17. The method of claim 16, further comprising:
reducing the second part of the third portion exposed by the control electrode to form an input area disposed adjacent to the first portion and comprising a metal layer, an output area disposed adjacent to the second portion and including a metal layer and a channel area disposed between the input area and the output area, after the providing the control electrode.

18. The method of claim 15, wherein the patterning the semiconductor layer and the conductive layer comprises:
providing a photoresist layer on the conductive layer;
firstly ashing the photoresist layer to remove a portion of the photoresist layer which overlaps the third portion of the semiconductor pattern using a mask, wherein the mask comprises a half-transmissive area which overlaps the third portion of the semiconductor pattern and a non-transmissive area which overlaps the first portion and the second portion of the semiconductor pattern;
secondly ashing the photoresist layer to expose a portion of the conductive layer, which overlaps the third portion of the semiconductor pattern; and
etching the conductive layer to expose the third portion of the semiconductor pattern.

19. The method of claim 15, wherein the patterning the semiconductor layer and the conductive layer further comprises:
providing a data line connected to the input electrode of the first thin film transistor and disposed in the peripheral area.

20. The method of claim 19, wherein the data line overlaps the semiconductor pattern.
